(19) United States
(12) Patent Application Publication
(10) Pub. No.: US 2002/0093088 A1
(43) Pub. Date: Jul. 18, 2002

(54) High density integrated circuits and the method of packaging the same

(76) Inventor: Daniel Wang, Markham (CA)

Correspondence Address: Salvatore J. Abbruzzese, HOFFMANN & BARON, LLP, 6900 Jericho Turnpike, Syosset, NY, 11791, US

(21) Appl. No.: 10/057,448

(22) Filed: Jan. 25, 2002

Related U.S. Application Data
(63) Continuation of application No. 08/761,365, filed on Dec. 9, 1996, now abandoned.

(51) Int. Cl. H01L 23/48

(52) U.S. Cl. 257/693; 257/694; 257/735; 257/738

(57) ABSTRACT

A method of increasing the packaging density of input/output interconnections between the semiconductor chip and substrate is described. Fine insulated wire is utilized for the connections to bonding pads provided selectively on the semiconductor chip without limiting to locating them along the periphery of the chip. The connections are made easily and quickly with the ball bonding process.

### BACKGROUND OF THE INVENTION

This invention relates to integrated circuit (IC) devices and more particularly relates to methods of packaging with high density input/output (I/O) interconnections between the semiconductor chip and the substrate in such IC devices.

IC devices provide a large variety of functions for electronic equipment such as computers, electrical controls, audio and video equipment and communication equipment. They serve as the key component in such equipment. Their application is ever increasing into all other equipment ranging from cameras, calculators to appliances widely used in all households. The pervading trend in the production of many equipment, particularly in electrical and electronic equipment is the relentless reduction of their physical size ever smaller, the ability to process increasingly larger amounts of information at faster speeds, and all at a lesser manufacturing cost. Due to the wide application of IC devices in such a wide variety of equipment, their packaging or assembly becomes a critical step in the manufacturing process of the equipment employing such devices. Thus, the semiconductor packaging industry is constrained by the current trend described succinctly as “faster, denser and cheaper”, namely, faster microchips must be provided in denser packages at lower costs than current packaging solutions. The common element of each packaging solution is that it must make some form of interconnection from the microchip in such IC devices. When the microchip is connected to a carrier substrate, this component is known as a module or semiconductor package. This process is described as semiconductor assembly and packaging.

In order to harness the power of the microchip for application purposes, each chip must be assembled into a semiconductor package using some form of fine attachment process to connect to the output terminals on its surface areas commonly referred to as bonding pads or in brief, bond pads. Three main processes are commonly employed in semiconductor packaging, namely, Tape Area Bonding (commonly referred to as TAB which is also known as Tape Carrier Package or TCP), Wire Bonding, and Controlled Collapse Chip Connection or C4 (more commonly referred to as Flip Chip). Wire bonding is the dominant interconnection process used, estimated at approximately 95% of all semiconductor packaging, TAB is second at approximately 2%, Flip Chip is at approximately 2%; and various other interconnecting processes at the remaining 1%.

In TAB bonding of semiconductor packages, the bond pads are usually provided solely along the perimeter of the microchip; and the chip is mounted onto a flexible carrier with its bond pads connected to mating circuitry on the flexible carrier. Gold bumps typically act as the interconnection medium between the microchip bond pads and the circuitry on the flexible carrier.

Traditionally, wire bonding technology has been restricted to attaching bare conductive wire to the bond pads which are provided solely around the perimeter of the microchip, the number of bond pads is limited in order to maintain the required spacing between neighboring pads (commonly referred to as “pad pitch”) to avoid contact causing short circuiting problems. Heretofore, many attempts have been made to increase the number of I/O connections. In U. S. Pat. No. 5,444,303 to Jonathon Greenwood et al, bond pads having a triangular shape are provided over the perimeter of the microchip to increase the number of bond pads; however, the effective increase in the number of bond pads still falls far short of the increasing demand for higher performance, I/O dense ICs. Another method commonly employed to increase I/O density as shown in U. S. Pat. No. 5,468,999 to Paul T. Lin et al, is by forming the bond pads in two staggering rows around the perimeter of the microchip as illustrated in FIG. 2. Such method of packaging is not only still limited by the physical size of the perimeter of the microchip, but it is also more costly due to the increased precision required to produce at a substantial premium such fine pitched wire bonds. Also, the tight spacing or fine pitch between neighboring bonds makes engineering changes or rework of the packaging extremely difficult and in many cases almost impossible.

In flip chip bonding of semiconductor packages, bumps of solder are directly attached to the microchip bond pads which are typically made of metallized aluminum with additional underbumped metallurgy and ranging in dimension in the order of 3 to 6 mils (50 to 150 microns) diameter on a spacing of typically 9 to 20 mils (225 to 500 microns) pitch, and it can be arranged in an area array which may be located at any selected locations of the microchip. In U. S. Pat. No. 5,490,040 to Gene J. Gaudenzi et al, it is shown a flip chip construction in which a microchip is provided with a plurality of bond pads in a plurality of selected areas. Solder balls are provided at these bond pads which are aligned with a configuration of terminal pads formed on a multilayered epoxy glass substrate. Such a multilayered composite construction provides an increased number of I/O connections; however, it is again currently complex in overall composite structure and is also costly to use producing currently poor yields relative to the high yields achieved by conventional methods of IC packaging.

The extent that industry would seek to obtain an increase in number of I/O is shown in U. S. Pat. No. 5,530,287 to Thomas P. Currie et al, in which only a relatively small increase in the number of I/O is obtained by providing three coplanar rows of ultra slender terminal pads on the perimeter of selected layers of a multilayered substrate. Each row of terminal pads are connected to the desired substrate layer by via conductors instead of the use of stepped or “bonding shelf” type substrates of prior art. Both constructions would still require the use of specially designed and costly to produce multilayered substrates.

In wire bonding of semiconductor packages, fine bare conductive wires made of either gold or aluminum are welded directly onto the microchip bond pads to achieve such interconnections. The wires are then fanned out and attached to similar pads or leads usually spaced much greater then 10 mils (250 microns) apart on the connecting substrate or carrier module. Wire bonding is the most popular packaging method, because it provides a flexible method of interconnecting the microchip to the substrate for I/O redistribution (commonly known as “fan out”). Wire bonding can be visualized as being similar to a sewing machine stitching and spot welding a conductive thread from the semiconductor microchip to the larger carrier package. The fragile wires are then covered by an encapsulating compound, usually epoxy, to protect them from physical damage. The wire bonding process is carried out at a very microscopic level as it stitches onto typically 2 mils (50 microns) square bond pads on the microchip which are spaced apart only 6 mils (150 microns) by using wires of 1 to 2 mils (25 to 50 microns) in size which is finer than human hair. Bond pads cannot be placed closer together, because of current limitations in the wire and wire bonding equipment due to at least four reasons: firstly, short circuiting may occur when fine bare wires are stitched closely adjacent to one another; secondly, the short circuiting problem may be worsened by the epoxy wire encapsulation process due to “wire sweep” causing wires to touch as the flowing epoxy compound unintentionally changes the critical spacing requirement between adjacent wires; thirdly, wires cannot be made finer with existing wire making processes and because of metallurgical limitations; and fourthly, the welding tools, known as bonding head capillaries, through which the wire is threaded may contact adjacent wires after having bonded prior wires to the chip bond pads causing short circuiting and damage to the wires during assembly. Capillaries cannot be made too narrow otherwise their mechanical strength and structural integrity would be compromised thus impeding their effectiveness.

There are basically two metal compositions used for making bonding wires today. One is the use of 99.9% pure gold, the other is aluminum alloy consisting of mainly aluminum with 1% of silicon or with 2% of magnesium. It is partly the metallurgical properties of these two metal types (gold versus aluminum) that have influenced the development of basically two different methods of attaching fine bonding wire for microelectronic interconnection purposes. Gold wire is normally attached using thermocompression or thermosonic ball bonding whereas aluminum alloy wire is connected by using ultrasonic wedge bonding since currently available aluminum wire is not conducive to the ball bonding operation. In addition, ball bonding by far is the most cost effective and the most widely available packaging interconnection method today. Ball bonding with gold wire provides acceptable connections but the intermetallic compound formation problems of mating two dissimilar metals, namely gold of the gold wire and aluminum of the metallized aluminum bonding pads, can negatively affect bond reliability. Compared to ball bonding, the wedge bonding process is relatively slow and rather inflexible (only unidirectional bonds) and it does not lend itself to automation to achieve high volume and high I/O production capabilities. Ball bonders have typically double the throughput rate of Wedge bonders and Ball bonders are rather flexible due to their ability to produce omnidirectional bonds.

### SUMMARY OF THE INVENTION

It is a principal object of the present invention to provide a method of microelectronic circuit packaging in which a plurality of bond pads may be formed on the entire surface of the microchip in an area array configuration rather than just around its perimeter.

It is another object of the present invention to provide wire bonding of connection wires to the area array configured bond pads of the microchip with insulated wire.

It is another object of the present invention to provide microelectronic circuit packaging with ultra fine pitch between adjacent wires without potential short circuit problems.

It is another object of the present invention to provide microelectronic circuit packaging with extremely reliable mating between the bonding wires and the bond pads.

It is yet another object of the present invention to provide microelectronic circuit packaging in which Multichip modules (MCMs) may be produced using direct chip-to-chip connections.

It is still yet another object of the present invention to provide microelectronic circuit packaging which is simple, inexpensive, reliable, and may be produced quickly to meet the demands of the industry.

The method comprises of forming a plurality of aluminum metallized bonding pads at a plurality of locations accessing the entire surface area of the microchip, and insulated aluminum alloy wires are ball bonded to the bonding pads of the microchip and the terminal pads of the connecting substrate forming the microelectronic device.

### BRIEF DESCRIPTION OF THE DRAWINGS

Other objects and advantages of the present invention will become apparent from the following detailed description of the preferred embodiments thereof in connection with the accompanying drawings in which

FIG. 1 is a schematic elevation diagram showing the bonding pads provided around the perimeter of a microchip in prior art microelectronic circuit devices.

FIG. 2 is a schematic elevation diagram showing the bonding pads provided in two staggered rows around the perimeter of prior art microelectronic circuit devices.

FIG. 3 is a schematic elevation diagram showing the full array of a plurality of bonding pads formed over the entire surface of the microchip according to the present invention.

FIG. 4 is a schematic elevation diagram showing the interstitially depopulated array of a plurality of bonding pads formed over the entire surface of the microchip according to the present invention.

FIG. 5 is a schematic elevation diagram showing the random array of a plurality of bonding pads formed at selected locations over the entire surface of the microchip according to the present invention.

FIG. 6 is an isolated and enlarged partial section elevation side view showing an insulated aluminum wire ball bonded to a bonding pad of a microchip disposed on a substrate.

FIG. 7 is an isolated top elevation partial view showing the random placement of bond wires connected to bonding pads of a microchip according to the present invention.

FIG. 8 is a perspective elevation view of a Multichip module (MCM) having a plurality of microchips using direct chip-to-chip wire connections according to the present invention.

### DETAILED DESCRIPTION OF THE PREFERRED EMBODIMENTS

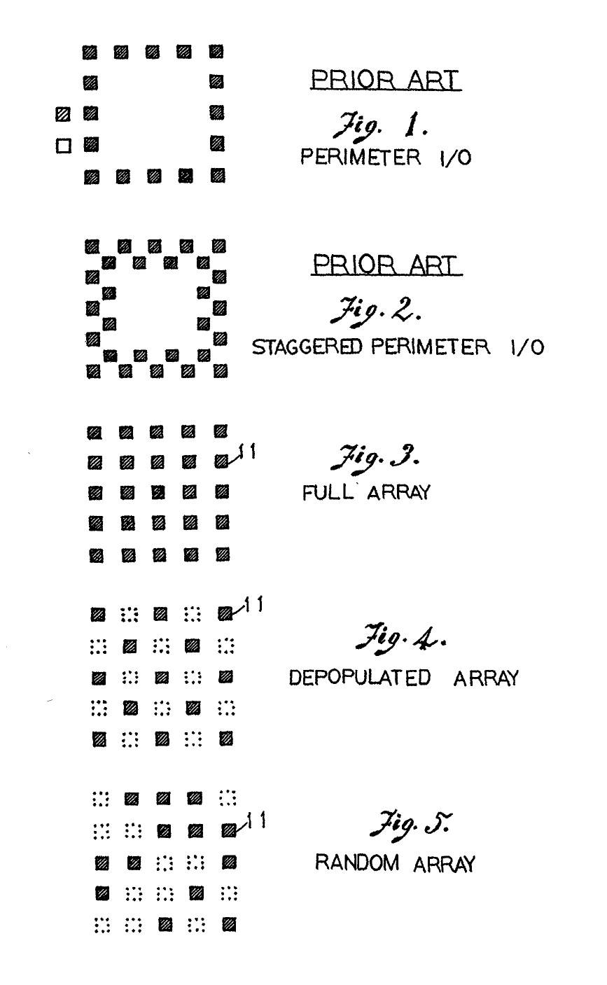

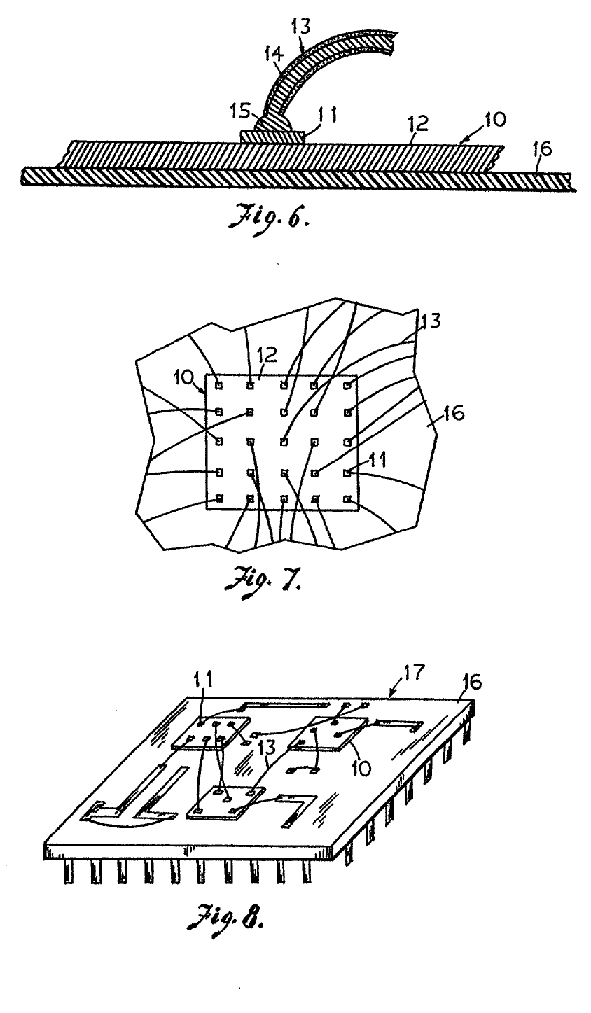

With reference to the drawings wherein like reference numerals designate corresponding parts in the several views, a microchip 10 having a full area array of a plurality of bond pads 11 formed thereon is best shown in the schematic diagram in FIG. 3. The bonding pads 11 are comprised of metallized aluminum. With the full utilization of the entire surface area of the microchip surface 12 typically from 900 to 10000 I/O connections may be made on a single microchip having a die size (i.e. width of chip) of 3 to 10mm (120 to 400 mils) respectively given a bond pitch of 4 mils (100 microns). Such a high density of I/O interconnections are many times more than the modest provisions offered by conventional wire bond connection methodology which adopts a single rowed or staggered rowed bonding pattern around the perimeter of the microchip as presently shown in the schematic diagrams in FIGS. 1 and 2. For simplicity of illustration, five columns and five rows of bond pads are shown on the entire surface 12 of the microchip 10 in FIG. 1. Such extremely high number of I/O connections have not been achieved by wire bonding onto bond pads arranged around the perimeter of the microchip. Furthermore, an interstitially depopulated array of bond pad pattern or matrix as best shown in FIG. 4, or a randomly depopulated array of bond pad pattern or matrix as best shown in FIG. 5 may be provided. The randomly depopulated array is particularly advantageous for use with a microchip which may have faulty areas that are not usable. Also, it simplifies the selection of locations for forming the bond pads. Alternatively, unused areas may be reserved for potential future repair or rework of the microelectronic circuit package. Such flexibility and provision cannot be achieved with microchips having I/O areas provided only around their perimeter.

Aluminum wire 13 having an insulated outside coating 14 is used for ball bonding to bond pad 11. An aluminum wire such as that shown in U. S. Pat. No. 4,860,941 to Alexander J. Otto may be used for such a purpose. Such an insulated aluminum wire has the necessary property that permits an axisymmetric bonding ball to be formed. This proper ball formation is critical for producing reliable ball bonds 15. Gold wire having an outer insulated coating such as that shown in U. S. Pat. No. 5,396,104 to Masao Kimura may also be used. However, insulated aluminum wire is preferred, since both the bond pad and the connecting wire are made of aluminum, a strong bond is formed between the aluminum wire and the metallized aluminum bond pad to provide a reliably high quality connection due to the homogeneous material of the two mating parts. Also, aluminum wire is of a much lower cost than gold wire and yet it can resist higher temperatures, more severe vibrations, higher G-loading, and radiation hardening than the latter. Since the aforementioned aluminum wire is ball bondable like gold wire, the ball bonding operation may be carried out expeditiously in a widely available and automated fashion instead of wedge bonding which was the only means heretofore for bonding aluminum wire. Furthermore, since the bond wires 13 are insulated, it alleviates the problem of short circuiting due to their contacting one another which is not permissible in prior art devices using bare bond wires, and also ultra fine insulated aluminum wire thinner than 15 microns may be produced as the outer insulation would provide the protection and rigidity (“stiffness”) required by the wire. The ultra fine bond wire permits the provision of smaller bond pads on the microchip such that an increased number of bond pads with a coarser pitch may be formed on the microchip, and in turn an even higher number of I/Os may be provided therein. As the bond wires are insulated, the placement and looping of such wires are not as critical in the packaging process, making the process less complex and thus it may be carried out at a much faster speed.

Aluminum wires 13 are connected to terminal pads on the substrate 16 in the conventional manner so as to form the final IC. A protective epoxy coating may be applied to the IC. Since the bond wires 13 are insulated, no potential short circuiting among the bond wires may occur even if the bond wires change their positions to contact one another due to “wire sweep”. For the above reasons, the IC packaging according to the present invention may be carried out to meet the industry's demand for “cheaper, faster, and denser” microchips.

A Multichip module 17 as best shown in FIG. 8 may be formed with the present invention by making use of the insulated wire to produce direct chip-to-chip connections among a plurality of microchips 10 disposed on a single layer substrate 16. The capability of making direct chip-to-chip connections eliminates the critical drawback of conventional methods in using composite multilayered substrates for making MCMs in which connections among the microchips are attached and connected to a high density multilayered substrates with a relatively dense network of fine connection or trace lines provided in the various substrate layers as shown in U. S. Pat. No. 5,373,188 to Kazumari Michii et al. Such a composite multilayered substrate is complex and costly to produce whereas a simple single layer substrate is all that is required for producing the MCM of the present invention. Furthermore, the routing of the trace lines in the high density substrate construction is inflexible due to the density of the lines that must be provided on the limited space available in each layer. With the direct chip-to-chip connections of the present invention, not only is the significant cost for a high density substrate eliminated, the interconnection cost may be halved, since a direct chip-to-chip connection with the insulated wire may be achieved with only one wire bond whereas the indirect connections between chips using the trace lines in the multilayered substrate require two wire bonds as shown also on U. S. Pat. No. 5,373,188 to Kazumari Michii et al. Using an insulated wire such as an insulated aluminum wire enables the direct chip-to-chip connections to be made beginning at the source chip's aluminum metallized pad to the insulated aluminum wire and terminating at the destination chip's aluminum metallized pad. All the components involved are made of the same metal, so there are no problems due to interconnection interfaces between dissimilar metals. On the other hand, with indirect chip-to-chip connections such as that used in flip chip, a variety of dissimilar metal interfaces are provided beginning with the aluminum metallized pad of the source chip connected to interfaces commonly comprising of chrome, copper and gold layers from which a copper pad is then connected to and leading to copper wire tracings in the connecting substrate that meets with the tin and lead solder joint; only to revisit again in reverse order the same variety of different metal interfaces to arrive at the aluminum metallized pad of the destination chip. Such interconnections of component parts of different metals could create a potential for reliability problems due to the possible poor adhesion of dissimilar layers and the formations of bond weakening intermetallic compounds.

Furthermore, the present invention addresses the major problem in the IC industry of the “pad limited” die (the number of bonding pads determines the die size not the circuitry) due to the peripheral bonding of high I/O devices . The present invention assists in producing chips dramatically reduced in size that have the same I/O performance of much larger peripherally bonded chips. Thus, it permits die shrink. The advantage of die shrink or smaller die is that more physically smaller microchips may be formed outside of the defective region of a semiconductor wafer, therefore, it increases the yield of the production of the microchip to result in dramatic cost savings and higher production yields.

Various modifications can be made without departing from the spirit of this invention or the scope of the appended claims. The embodiments set forth in this disclosure are given as examples and are in no way final or binding. In view of the above, it will be seen that several objects of the invention are achieved and other advantages are obtained. As many changes could be made in the above construction and methods without departing from the scope of the invention, it is intended that all matter contained in the above description shall be interpreted as illustrative and not in a limiting sense.

I claim:

1. A method of packaging a high density integrated circuit with at least one microchip disposed on a substrate comprising,
forming an array of a plurality of bonding pads on the entire surface of said microchip,
attaching insulated bond wires directly onto said bonding pads and onto terminal pads disposed on said substrate.

2. A method of packaging a high density integrated circuit according to claim 1, wherein said bonding pads and said bond wires are made of the same metal, and said bonding pads are located at selected locations over the entire surface of said microchip.

3. A method of packaging a high density integrated circuit according to claim 2, wherein said insulated bond wires are insulated aluminum wires and said bonding pads are made of metallized aluminum, and said insulated aluminum wires are attached to said bonding pads on said microchip by a ball bonding process.

4. A method of packaging a high density integrated circuit according to claim 3 wherein said insulated aluminum wires are finer than 15 microns and having an oxidized outer insulation.

5. A method of packaging a high density integrated circuit having at least one semiconductor microchip disposed on a substrate having a plurality of terminal pads provided thereon, comprising
forming an array of a plurality of bonding pads in a plurality of rows and columns over the entire surface of said microchip,
connecting selected bonding pads on said microchip with selected terminal pads on said substrate with insulated bond wires wherein said bond wires are attached to said bonding pads with a ball bonding process.

6. A method of packaging a high density integrated circuit according to claim 5 including coating and integrated circuit with a protective encapsulating material.

7. A method of packaging a high density integrated circuit according to claim 6 wherein said bonding pads are located at selected locations over the entire surface of said microchip.

8. A method of packaging a high density integrated circuit according to claim 7 wherein a plurality of semiconductor microchips are disposed on said substrate, and interconnections among selected bonding pads on said microchips are provided by insulated aluminum alloy wires bonded to said selected bonding pads.

9. A high density integrated circuit package comprising
at least one semiconductor microchip element disposed on a substrate having a plurality of terminal pads provided thereon,
a plurality of connection bonding pads formed at selected locations over an active surface of said microchip,
insulated bond wires connected by ball bonding directly to said bonding pads on said microchip and said terminal pads on said substrate.

10. A high density integrated circuit according to claim 9 wherein said bonding pads are made of metallized aluminum, and are located in a plurality of rows and columns dispersed over the entire active surface of said microchip.

11. A high density integrated circuit according to claim 10 wherein said insulated bond wires are insulated aluminum alloy wires having an oxidized outer insulation.

12. A high density integrated circuit according to claim 11 including a protective encapsulating material applied over said microchip.

13. A high density integrated circuit according to claim 12 wherein said bonding pads are formed in selected random locations over the surface of said microchip.

14. A high density integrated circuit according to claim 13 including a plurality of microchips disposed on said substrate, said plurality of microchips having said bonding pads formed at a plurality of selected random locations dispersed over the entire surface thereon, and a plurality of said bond wires interconnecting directly between selected bonding pads among said microchips.
